(19) United States
(12) Patent Application Publication
(10) Pub. No.: US 2012/0112780 A1
(43) Pub. Date: May 10, 2012

(54) OPEN TOP BURN IN SOCKET

(75) Inventor: Brian Groeger, Lawrenceville, NJ (US)

(73) Assignee: ARIES ELECTRONICS, INC., Bristol, PA (US)

(21) Appl. No.: 13/291,437

(22) Filed: Nov. 8, 2011

Related U.S. Application Data
(60) Provisional application No. 61/411,250, filed on Nov. 8, 2010.

(51) Int. Cl. G01R 31/00

(52) U.S. Cl. 324/756.02

(57) ABSTRACT

A test socket for an integrated circuit device includes a base for receiving the circuit device and a frame movable linearly toward and away from the base. Springs bias the frame away from the base. Device holders are movable substantially linearly on the frame between a closed position where the device holders are in proximity to one another and an open position where the device holders are remote from one another. Cams move the device holders between the open and closed positions in response to movement of the frame toward and away from the base.

### PRIORITY

This application claims priority on U.S. Provisional Patent Appl. No. 61/411,250, filed on Nov. 8, 2010 and entitled “Open Top Burn-in Socket”, the entire contents of which are incorporated herein by reference.

### BACKGROUND OF THE INVENTION

1. Field of the Invention

The invention relates to a socket for testing an integrated circuit device.

2. Description of the Related Art

Integrated circuit devices are used in many types of electronic equipment. A typical electronic product will include many circuit boards, each of which includes several integrated circuit devices soldered thereon. Integrated circuit devices that have been soldered to a circuit board are difficult to remove. As a result, a damaged integrated circuit device may require the entire circuit board to be discarded, thereby imposing a significant cost penalty on the manufacturer of the device. As a result, integrated circuit devices generally are subjected to rigorous testing prior to mounting on a circuit board. The testing generally is carried out a specified temperature that is intended to reflect the temperature to which the integrated circuit device will be subjected during use. Additionally, the testing is carried out for a specified time. Integrated circuit devices that do not pass the tests are considered defective and can be discarded prior to being soldered onto a circuit board.

The test sockets that are used to test integrated circuit devices at controlled temperatures often are referred to as burn-in sockets. Several burn-in sockets typically are mounted on a mother board. Each of the test sockets includes a receptacle dimensioned to receive the integrated circuit device. Each test socket also will include a plurality of contacts that are disposed to engage the conductive leads of the integrated circuit device. Each test socket also has structure for holding the integrated circuit device in position adjacent the motherboard and the contacts on the motherboard.

Some test sockets have a frame-shaped receptacle into which the integrated circuit device is placed. These test sockets then may have a clam-shell cover that can be rotated over the receptacle to hold the integrated circuit device adjacent the mother board. These test sockets require the covers to be rotated individually into the closed position. Test sockets of this type are not well-suited to large volume testing in that the covers generally must be rotated separately by hand. Other test sockets are configured to move a cover member laterally parallel to the top surface of the integrated circuit device and into positions adjacent the top surface of the integrated circuit device. These test sockets generally have a lever that must be rotated to move gripping devices into positions for engaging the surfaces of integrated circuit device. Test sockets of this type require space for moving the lever. Additionally, arrays of test sockets of this type may require a specially configured cover plate with openings that permit access to the levers.

The subject invention has been made in view of the above-described problems with existing test sockets.

An object of the invention is to provide a test socket, such as a burn-in test socket, that enables the integrated circuit device to be gripped and released easily in an automated manner.

A further object of the invention is to provide a test socket with minimal space requirements.

### SUMMARY OF THE INVENTION

The invention relates to a burn-in test socket having a base with opposite top and bottom surfaces. The bottom surface of the base is mountable in opposed relationship to a mother board. The top surface of the base is configured to receive an integrated circuit device from above. More particularly, the top surface of the base may include a rectangular receptacle into which the integrated circuit device can be placed. Tweezer slots may be disposed at the periphery of the receptacle to accommodate tweezers for placing the integrated circuit device in the receptacle or for removing the integrated circuit device from the receptacle. The base further includes connection means for establishing electrical connection between leads of the integrated circuit device and circuit components on the mother board.

The test socket further includes a substantially rectangular frame mounted above the top surface of the base. Guides extend rigidly from the base and are disposed at the corners of the frame. The guides enable the frame to be moved vertically toward and away from the base. Biasing means, such as springs, preferably are disposed between the base and the frame and bias the frame away from the base. However, the frame can be pushed down toward the base, thereby compressing the biasing means. The biasing means may be disposed respectively near the four corners of the rectangular frame.

Device holders are provided for holding the integrated circuit devices in the receptacle formed in the base. The device holders are mounted to the frame for movement relative to the frame from a first position where the device holders are in proximity to one another and at least partly in the opening of the frame and a second position where the device holders are farther from one another. The device holders are substantially above the integrated circuit device on the base when the device holders are in the first position. However, the device holders are disposed to permit the integrated circuit device to be placed on or remove from the base when the device holders are in the second position.

Cam means are provided for moving the device holders between the first and second positions as the frame is moved toward and away from the base. The cam means preferably comprises two cams mounted at opposed positions on the base for rotation about axes substantially transverse to the moving direction of the frame toward the base and preferably transverse to the moving directions of the device holders toward or away from one another. More particularly, each cam can be rotated between a first position when the test socket is open for receiving or removing an integrated circuit device and a second position where the test socket is closed for holding an integrated circuit device during a test. Each cam has a curved surface that faces up and out when the cam is in the first position. Each cam further has a flat surface that faces down and out when the cam is in the first position. The flat surface of each cam is aligned substantially vertically when the cam is in the second position. Links are mounted to the cams for rotation with the cams. Each link projects out beyond the curved surface of the respective cam.

Torsion spring means are mounted in proximity to the axes of about which the cams rotate for urging the cams and the links toward the second position of each cam.

Cam followers project down from the frame for engaging the cams. More particularly, the cam followers engage the curved surfaces of the respective cams when the cams are in the first position. On the other hand, the cam followers engage the flat surfaces of the cams and can slide vertically along the flat surfaces of the cams when the cams are in the second positions. A downward force on the frame will cause the cam followers to ride along the curved surfaces of the respective cams and will rotate the respective cams from the first position toward the second position against the forces exerted by the torsion spring means. When the cams reach the second positions, further forces exerted on the frame will cause the cam followers to slide vertically along the flat surfaces of the cams.

Guide channels extend horizontally along inner surfaces of the frame and perpendicular to the axes about which the cams rotate. Thus, at least two guide channels extend toward one another from opposite sides of the frames.

Each device holder has a support that is mounted slidably on the guide channels extending in from one side of the frame. Thus, the supports of the device holders can move along the guide channels toward and away from one another. The supports of the device holders are connected pivotally to the ends of the links spaced outwardly from the cams and outwardly from the rotational axes about which the cams rotate. Each device holder further has at least one pressure pad that can move vertically relative to the respective support. Springs, such as wave springs, are provided in each device holder between the support and the pressure pad. The wave springs urge the pressure pads down away from the respective support and toward the base of the test socket. Opposed surfaces of the device holders are spaced away from one another and align with the inner edges of the frame when the cams are in the first position. Thus, the integrated circuit device can be mounted down through the frame and into the receptacle in the base when the cams are in the first position with the corresponding device holders moved away from one another due to the forces exerted by the torsion springs. However, the device holders are within the frame and above receptacle formed in the base when the cams are in the second position. Additionally the entire frame can be moved down toward the base when the cams are in the second position so that the pressure pads of the device holders can move down into engagement with an integrated circuit device mounted in the receptacle.

The test socket further includes latches mounted pivotally to the frame. The latches may be on edges of the frame that are perpendicular to the axes about which the cams rotate. Each latch has opposite top and bottom ends and is rotatable about a horizontal axis between the ends. The top end of each latch defines an actuator. The actuators of the opposed latches can be urged toward one another thereby causing the bottom ends of the latches to rotate away from one another. The bottom end of each latch defines a lock that can engage a locking surface on the base of the test socket. Springs urge the latches into an orientation where actuators move away from one another, and hence move the locks toward one another and into positions where the locks can engage the locking surfaces on the base of the test socket.

The spring means and biasing means described herein have the following effect. First, the torsion spring means urge the cams into the first position. Second, the biasing means urge the frame up and away from the base. Third, the latch springs urge the respective latches into positions for engaging the locking surfaces on the base.

The test socket initially is in an open position with the cams biased into the first position, with the latches disengaged from the locking surfaces on the base and with the frame urged up by the biasing means and away from the base. In this open position, the device holders are spaced from one another so that opposed surfaces of the device holders align with inner edges of the frame. Thus, an integrated circuit device can be moved from above through the frame and into the receptacle in the base of the test socket. A downward force then is exerted on the frame. This downward force moves the frame down against the forces of the coil springs and causes the cam followers on the frame to move against the curved surfaces of the cams. The engagement of the cam followers with the curved surfaces of the cams while the frame is moving down causes the cams to rotate from the first position toward the second position. As a result, the links rotate with the cams and cause the device holders to approach one another. More particularly, the supports of the device holders slide along the guide channels so that the device holders move into the interior of the frame and above the receptacle in which the integrated circuit device has been placed. Simultaneously, the frame continues its downward movement so that the pressure pads approach the integrated circuit device in the receptacle. After sufficient downward movement of the frame, the locks on the respective latches will align with the locking surfaces on the base. The latch springs then cause the latches to rotate into positions where the locks of the latches engage the locking surfaces on the base. This engagement will prevent the frame from moving up, but also will permit the frame to move down farther in response to continued forces on the frame. This downward movement of the frame is enabled as the cam followers slide along the vertically aligned flat surfaces of the cams while the cams are in the second position. Tests then can be conducted on the integrated circuit device. Upon completion of the test, a user merely urges the actuators of the latches toward one another so that the locks of the latches are released from the locking surfaces on the base. The biasing means between the base and the frame then will urge the frame up. Simultaneously, the torsion spring means mounted at the cams will rotate the cams from the second position back to the first position. This rotation of the cams will move the device holders into the open position. Tweezers then can be used at the tweezer slots to remove the integrated circuit devices from the receptacle.

### BRIEF DESCRIPTION OF THE DRAWINGS

FIG. 1 is a top perspective view of the test socket in accordance with the invention with the socket in an open position.

FIG. 2 is a top perspective view of the test socket in the closed position.

FIG. 3 is a perspective view of the bottom of the test socket.

FIG. 4 is a top plan view socket.

FIG. 5 is a front elevational view of the test socket.

FIG. 6 is a side elevational view of the test socket.

FIG. 7 is a cross-sectional view of the test socket taken along line 7-7 in FIG. 5 and showing the open position.

FIG. 8 is a cross-sectional view of the test socket similar to FIG. 7, but showing the closed position.

FIG. 9 is a cross-sectional view of the test socket taken along line 9-9 in FIG. 6 and showing the open position.

FIG. 10 is a cross-sectional view similar to FIG. 9 but corresponding to the closed position.

FIG. 11 is an enlarged view of the device holder in the open position.

FIG. 12 is an enlarged view of the device holder in the closed position.

FIG. 13 is a cross-sectional view taken along line 13-13 with the test socket in an open position.

FIG. 14 is a cross-sectional view similar to FIG. 13, but showing the test socket in the closed position.

### DETAILED DESCRIPTION OF THE PREFERRED EMBODIMENT

An open-topped test socket in accordance with the invention is identified generally by the 10 in the figures. The test socket 10 has a generally rectangular base 12 with opposite top and bottom surfaces 14 and 16. The top surface 14 includes a rectangular receptacle 18 configured to receive integrated circuit device (not shown). Opposed edge regions of the receptacle include slots 20 that can accommodate tweezers for removing an integrated circuit device from the receptacle 18 upon completion of a test. The bottom surface 18 of the base 12 will be positioned in opposed relationship to a motherboard that has circuitry for completing the test on the integrated circuit device. Electrical connection means extend between the top and bottom surfaces 14 and 16 of the base 12 to enable conductive leads of the integrated circuit device to be connected to the circuitry on the motherboard. Four L-shaped guides 22 extend up from the base 12 at the respective corners.

The test socket 10 further includes a substantially rectangular frame 24 positioned above the base 12 and within the area defined by the four corner guides 22. The guides 22 enable the frame 24 to be moved vertically toward and away from the base 12. Coil springs 25 are mounted between the base 12 and the frame 22 at the locations identified by the circular openings 26. The four coil springs 25 bias the frame 24 up and away from the base 12.

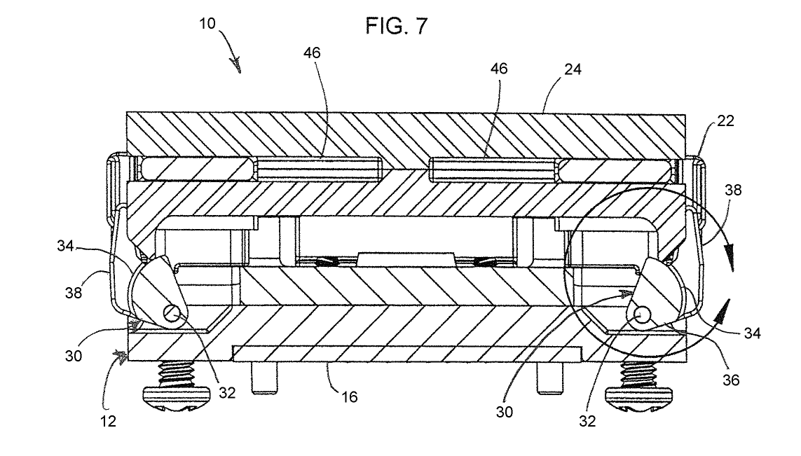

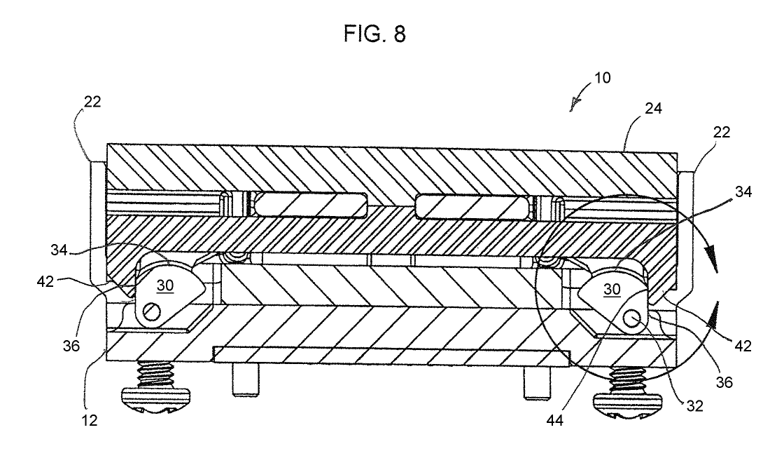

Cams 30 are mounted at two opposite sides of the base 12 and are rotatable about essentially horizontal axes 32. Each cam 30 can be rotated between a first or open position shown in FIG. 7 and a second or closed position shown in FIG. 8. Each cam 30 has a curved surface that faces out from the base 12 when the cam 30 is in the first position. However, the curved surface 34 faces up when the cam 30 is in the second position, as shown in the FIG. 8. Each cam 30 further as a flat surface 36 that is aligned vertically when the respective cam 30 is in the second position shown in FIG. 8. Torsion springs 38 are mounted in proximity to the cams 30 and urge the cams 34 toward the first position. Links 40 are mounted in proximity to the cams 30 and move as the respective cams 30 rotate about the axes 32.

The frame 34 has cam followers 42 that engage the cams 30. A downward force on the frame 24 in the position of FIG. 7 will cause the cam followers 42 to slide along the curved surfaces 34 of the respective cams 30 and will cause the cams 30 to rotate about the axes 32 inward from the first position shown in FIG. 7 toward the second position shown in FIG. 8 and against the biasing forces exerted by the torsion springs 38. This rotation of the cams 30 toward the second position will cause a corresponding rotation of the respective links 40. Each cam follower 42 has a vertical surface 44 that can slide vertically along the flat surface 36 of the respective cam 30 when the cam 30 is in the second position of FIG. 8.

The frame 24 is formed with guide channels 46 aligned horizontally and substantially perpendicular to the alignment of the rotational axes 32 of the cams 30.

The test socket 10 further includes device holders 50 for holding the integrated circuit device in the receptacle 18 in the base 10. Each device holder 50 has a support 52 slidably engaged in the guide channels 46 of the frame 24 so that the respective supports 52 can move horizontally toward and away from one another. The supports 52 are connected pivotally to the ends of the links 40 remote from the axes 32 about which the cams 30 rotate. Thus, rotation of the cams 30 and the links 42 will cause the supports 52 of the device holders 50 to move along the guide channels 46 toward or away from one another. The device holders 50 substantially align with the inner periphery of the frame 24 when the cams 30 are in the first position. However, the device holders 50 are disposed within the interior of the frame 24 and above the receptacle 18 in the base 12 when the cams 30 are in the second positions. Each device holder 50 further includes a pressure pad 54 that can move vertically relative to the respective support 52. Wave springs 56 are provided between the supports 52 and the pressure pads 54 for urging the pressure pads 54 down and away from the supports 52. The pressure pads 54 will engage the top surface of an integrated circuit device mounted in the receptacle 18 of the base 12 to hold the integrated circuit device in position for testing.

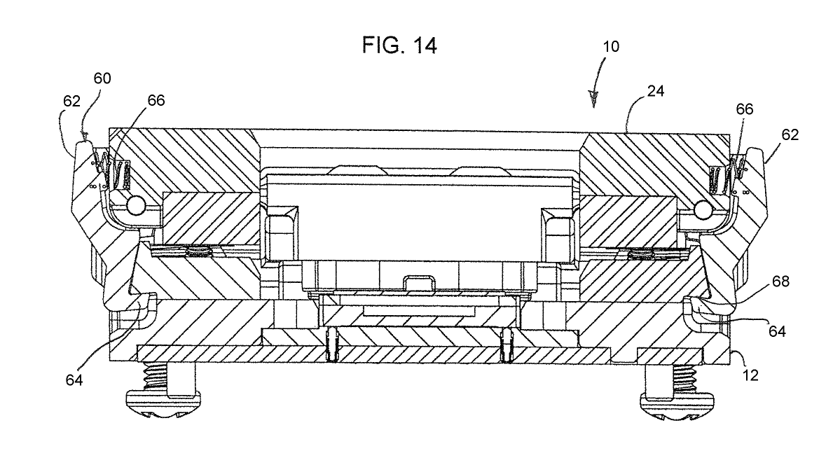

The sides of the frame 24 that are formed with the guide channels 46 have latches 60 mounted thereon at locations adjacent the outer periphery of the frame 24. Each latch 60 has opposite top and bottom ends and is pivoted to the frame 24 at a position between the top and bottom ends. The top end of each latch 60 defines an outwardly facing actuator 62. The bottom end of each latch 60 defines and inwardly facing lock 64. Latch springs 66 are disposed between the frame 24 and the actuators 62 of the respective latch 60 and urge the locks 64 of the latch 60 inwardly. The locks 64 of the latches 60 are configured to engage locking surfaces 68 formed on the base 12 as shown in FIG. 14. However, the actuators 62 can be squeezed toward one another against the forces of the latch springs 66 to rotate the latches 60 into positions where the locks 64 disengage from the locking surfaces 68 on the base 12.

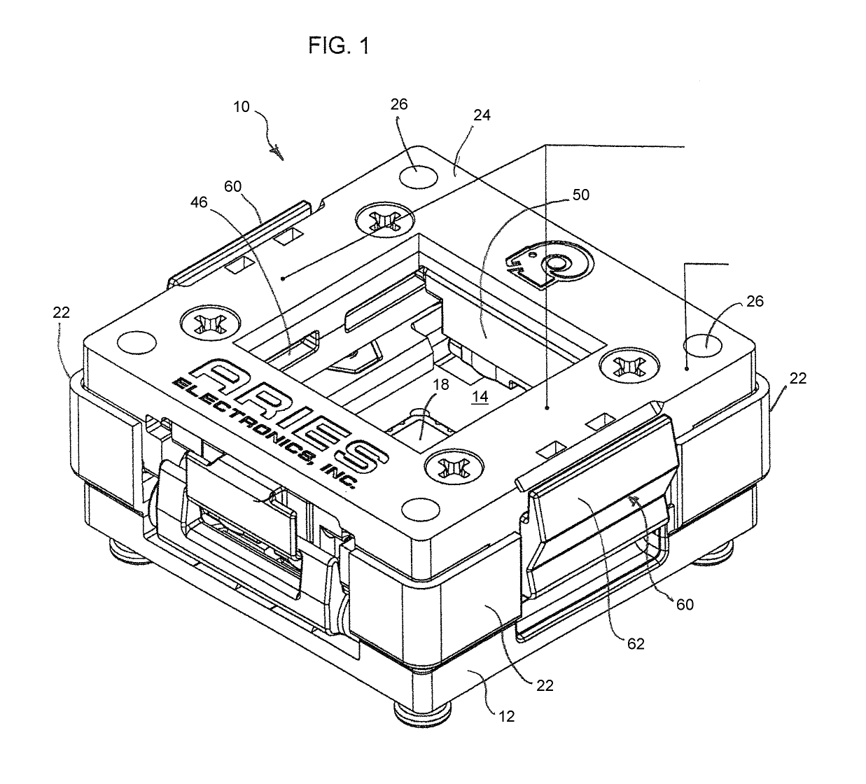

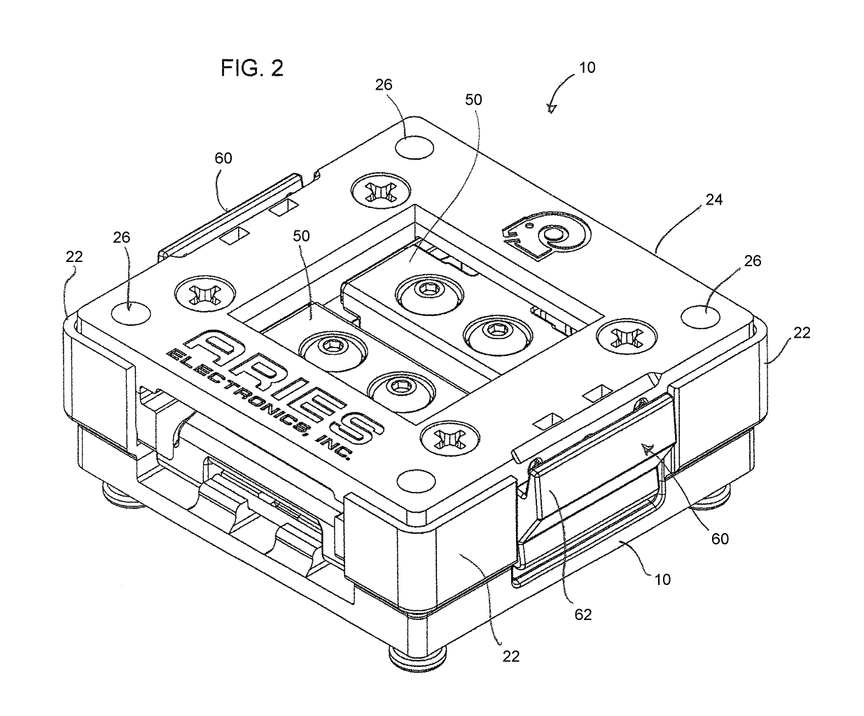

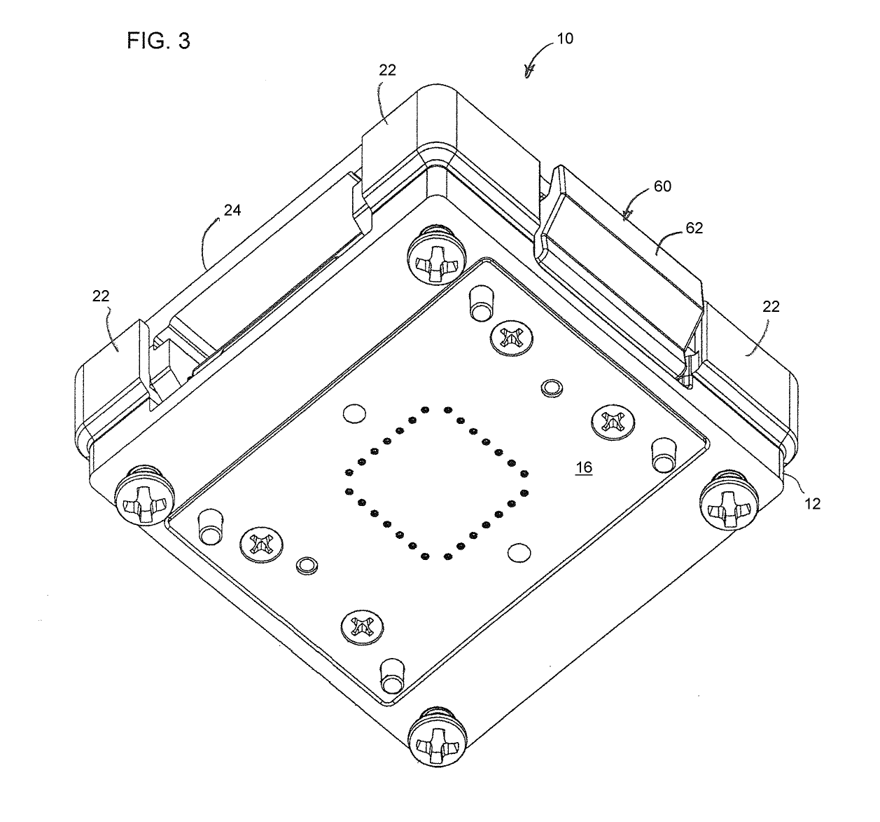

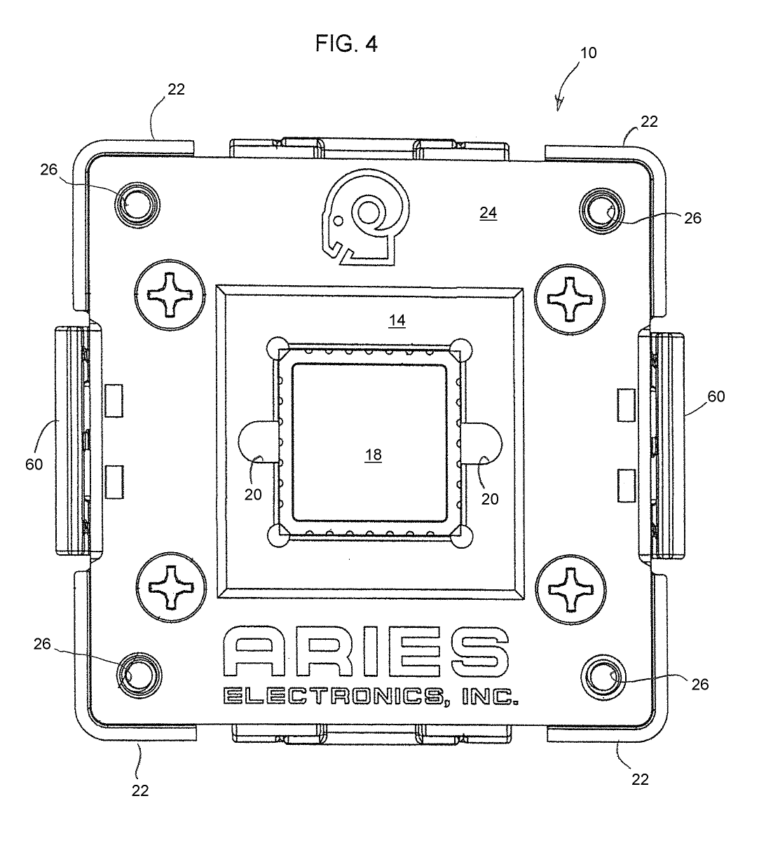

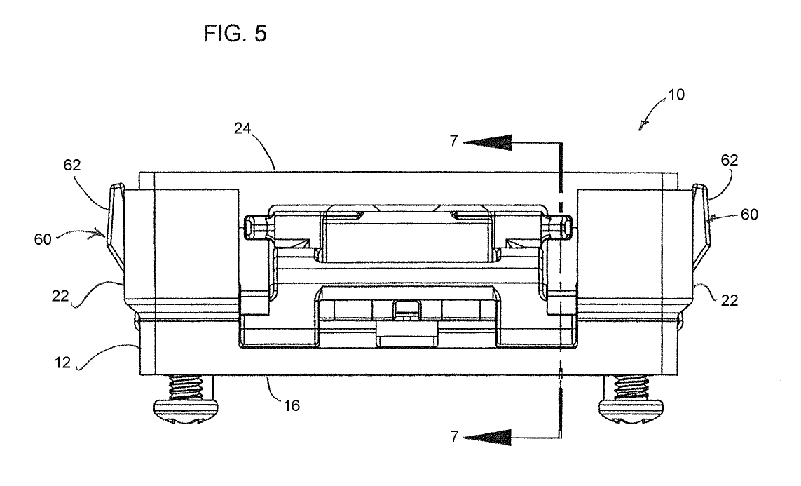

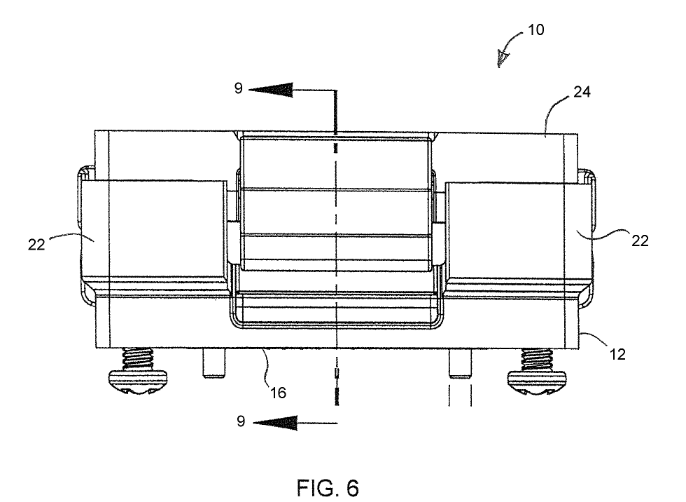

The test socket 10 initially is in the open position shown in FIG. 1. This open position can be achieved by squeezing the actuators 62 toward one another and permitting the coil springs 25 to urge the frame 24 up and away from the base 12, thereby simultaneously causing the cams 30 to rotate into the first position shown in FIG. 7. An integrated circuit device then is placed in the receptacle 18 in the base 12. An operator then pushes the frame 24 down against the biasing forces exerted by the coil springs 25. This downward movement of the frame 24 causes the cam followers 42 to slide along the curved surfaces 34 of the cams 30, thereby causing the cams 32 to rotate against the biasing forces exerted by the torsion springs 38 and toward the second position of FIG. 8. The links 40 move with the cams 30 and hence push the supports 52 of the device holders 50 along the guide channels 46 in the frame 24 and into positions above the integrated circuit device that has been deposited in the receptacle 18 of the frame 24. The flat surfaces 36 of the cams 30 align vertically when the cams 30 reach the second position. The vertical surfaces 44 cam followers 42 then can slide along the vertically aligned flat surfaces 36 so that the frame 24 can be pushed farther down toward the base 12. This downward movement of the frame 24 will urge the pressure pads 54 of the device holders 50 into engagement with the top surface of the integrated circuit device. Sufficient downward movement of the frame 24 will cause the locks 64 of the latches 60 to align with the locking surfaces 68 on the base 12. As a result, the latch springs 66 will cause the latches 60 to pivot so that the locks 64 of the latches 60 engage the locking surfaces 68 of the base to hold the frame 24 in proximity to the base 12 against the biasing forces of the coil springs 25. The frame 24 can be pushed farther down toward the base 12 so that the pressure pads 54 exert appropriate holding forces on the integrated circuit device in the receptacle 18 of the base 12.

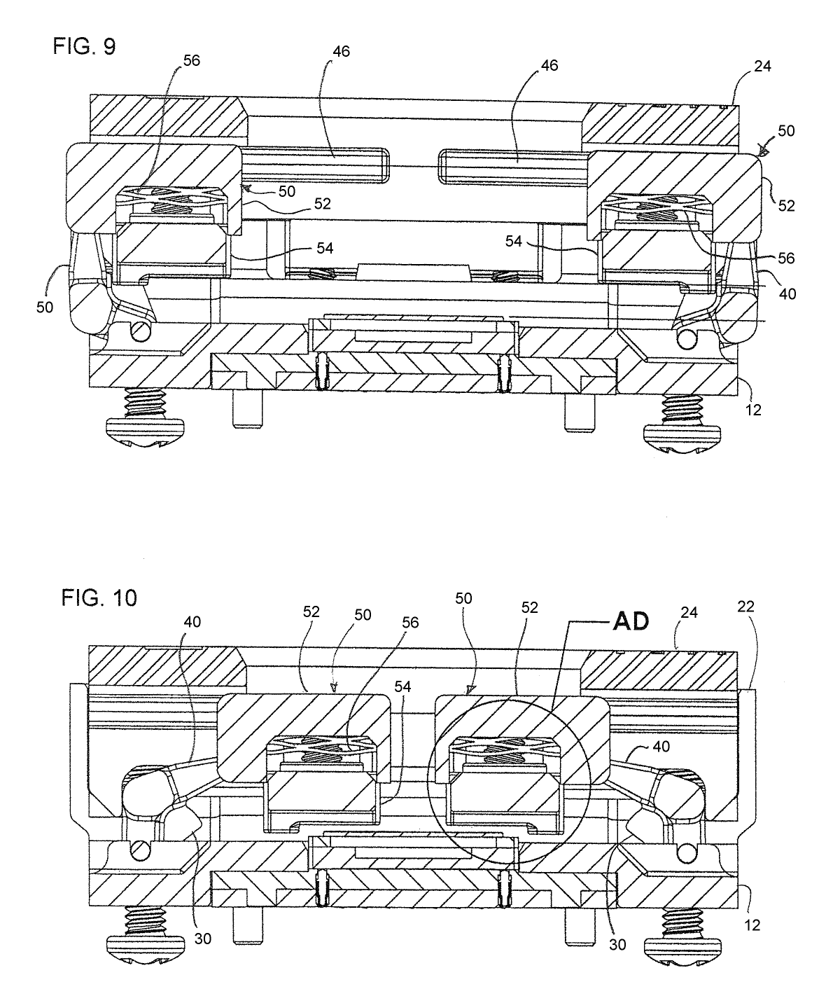

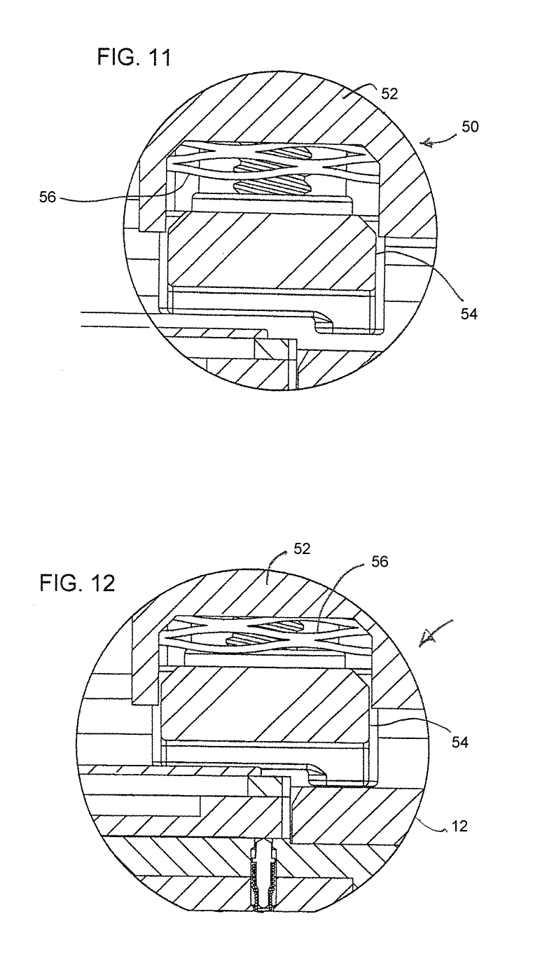

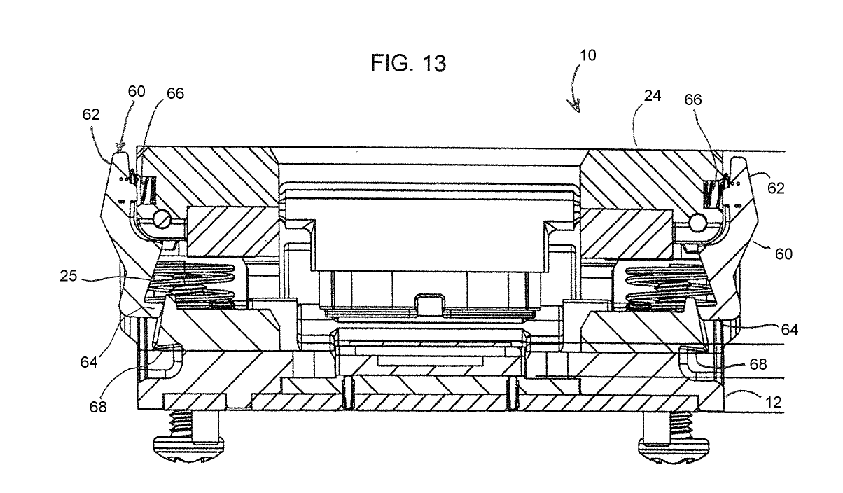

A test can be conducted on the integrated circuit device in a standard manner. Upon completion of the test, the operator squeezes the actuators 62 of the latches 60 toward one another to release the locks 64 from the locking surfaces 68. The coil springs then will urge the frame 24 up and away from the base 12. As a result, the torsion springs will rotate the cams 30 from the second position of FIG. 8 back toward the first position of FIG. 7. The links 40 will rotate with the cams 30 and will cause the device holders 50 to move into the open position of FIG. 9. An operator then can use tweezers or the like to remove the tested integrated circuit device from the test socket.

What is claimed is:

1. A test socket, comprising:
a base having a receptacle configured receiving an integrated circuit device;
a frame movably disposed for movement toward and away from the base, the frame having an opening for permitting access to the receptacle of the base;
biasing means for urging the frame away from the base;
device holders mounted to the frame for substantially linear movement relative to the frame from a first position where the device holders are in proximity to one another and at least partly in the opening of the frame and a second position where the device holders are farther from one another; and
cam means for moving the device holders relative to the frame as the frame is moved toward and away from the base.

2. The test socket of claim 1, wherein the cam means comprise first and second cams rotatably mounted to the base for rotation about axes substantially transverse to moving directions of the frame toward and away from the base and substantially transverse to moving directions of the device holders toward and away from one another.

3. The test socket of claim 2, wherein the cam means further comprises first and second cam followers formed on the frame and movable along the respective cams as the frame is moved toward and away from the base, the cam followers being configured for rotating the cams toward one another in response to movement of the frame toward the base and for holding the cams in a fixed position when the frame is in proximity to the base, the cam followers further being configured for following the cam as the frame is biased away from the base.

4. The test socket of claim 3, further comprising torsion spring means for biasing the cams rotatably away from one another.

5. The test socket of claim 3, further comprising links rotatable with the cams and extending from the cams to the respective device holders, the links moving the device holders toward the first position as the cams are rotated toward one another and moving the device holders toward the second position as the cams are rotated away from one another.

6. The test socket of claim 5, wherein the links are pivotably connected to the respective device holders.

7. The test socket of claim 5, wherein the frame includes guides slidably engageable with the device holders for guiding movement of the device holders substantially linearly between the first and second positions.

8. The test socket of claim 1, further comprising at least one latch for holding the frame in proximity to the base.

9. The test socket of claim 8, further comprising a latch spring for biasing the latch into a position for holding the frame in proximity to the base.

10. The test socket of claim 9, wherein the latch is pivotably mounted to the frame and is configured for engaging a lock on the base.

11. The test socket of claim 9, wherein the frame is substantially rectangular, the at least one latch comprising two opposed latches on opposite sides of the frame, the device holders being movable substantially parallel to the sides of the frame to which the latches are pivotably mounted.

12. The test socket of claim 1, wherein each of the device holders includes a support slidably movable along the frame in directions transverse to a moving direction of the frame toward the base and movable in unison with the frame along the moving direction of the frame toward the base, each of the device holders further having a pressure pad movably mounted to the support for movement toward and away from the base and configured for holding an integrated circuit device in the receptacle of the base.

13. The test socket of claim 12, wherein each of the device holders further includes a biasing member for urging the pressure pad away from the support and toward the base.

14. The test socket of claim 1, wherein the device holders are substantially outwardly from the opening in the frame when the device holders are in the second position.

15. A test socket for testing a circuit device, comprising:
a base for receiving the circuit device;
a frame movable substantially linearly toward and away from the base, the frame including an opening for enabling the circuit device to be placed on or removed from the base;
device holders mounted to the frame for movement substantially linearly relative to the frame from a first position where the device holders are in proximity to one another and at least partly in the opening of the frame and a second position where the device holders are farther from one another; and
cam means for moving device holders toward one another in response to movement of the frame toward the base and for moving the device holders away from one another in response to movement of the frame away from the base.

16. The test socket of claim 15, further comprising a latching means for releasably locking the frame to the base when the frame is substantially adjacent the base.

17. The test socket of claim 16, further comprising biasing means for urging the frame away from the base when the latching means release the locking out the frame to the base.

18. A test socket, comprising:
a base having a receptacle configured receiving a circuit device;
a frame movably disposed for linear movement toward and away from the base, the frame having an opening for permit access to the receptacle of the base;
springs for urging the frame away from the base;
device holder supports mounted to the frame for substantially linear movement relative to the frame from a first position where the device holder supports are in proximity to one another and at least partly in the opening of the frame and a second position where the device holder supports are farther from one another;
pressure pads movably mounted to the respective device holder supports, the pressure pads being biased toward the base and configured for holding a circuit device in the receptacle of the base;
cams for moving the device holder supports between the first and second positions as the frame is moved toward and away from the base; and
latches for releasably holding the frame in proximity to the base when the frame is substantially adjacent the base.
